(19) United States
(12) Patent Application Publication
(10) Pub. No.: US 2006/0060379 A1
(43) Pub. Date: Mar. 23, 2006

(54) Printed circuit board structure

(76) Inventor: Tseng Feng Mao, Hsin Chu (TW)

Correspondence Address: Keith Kline;PRO-TECHTOR INTERNATIONAL SERVICES, 20775 Norada Court, Saratoga, CA, 95070-3018, US

(21) Appl. No.: 10/946,244

(22) Filed: Sep. 20, 2004

(51) Int. Cl. H05K 1/11

(52) U.S. Cl. 174/262

(57) ABSTRACT

A printed circuit board structure includes three layer substrates and two layer metal sheets, the each substrate formed with a plurality of hole for conducting the each substrate one another. The two layer metal sheets are positioned between the two adjacent substrate, the each metal sheet is formed with grid array penetrated holes. So that the grid array penetrated holes 46, 48 of the metal sheet 36, 38 may be absorbed bent energy from the substrate 30, 32, 34, thus, the printed circuit board may be decrease the damage to increase the production yield.

### BACKGROUND OF THE INVENTION

1. Field of the Invention

The invention relates to a printed circuit board structure, and in particular to a printed circuit board may be decrease the damage to increase the production yield.

2. Description of the Related Art

Referring to FIG. 1, a conventional printed circuit board structure includes three layer substrates 10, 12, and 14. The substrate 10, 12, and 14 are formed with plurality of hole for conducting the each substrate one another. Two metal sheets 22 and 24 are positioned between the adjacent substrate. The each metal sheet is formed with hole for electrically conducting with the each substrate.

However, the conventional printed circuit board has following drawbacks.

Since the metal sheet is a piece of metal, so the substrate is easily bent in high temperature matter.

### SUMMARY OF THE INVENTION

An objective of the invention is to provide a printed circuit board structure, which may be decreased the damage to increase the production yield.

To achieve the above-mentioned object, the invention includes three layer substrates and two layer metal sheets, the each substrate formed with a plurality of hole for conducting the each substrate one another. The two layer metal sheets are positioned between the two adjacent substrate, the each metal sheet is formed with grid array penetrated holes. So that the substrate may be avoid bent in high temperature matter.

### BRIEF DESCRIPTION OF THE DRAWINGS

FIG. 1 is a schematic illustration view showing a conventional printed circuit board structure.

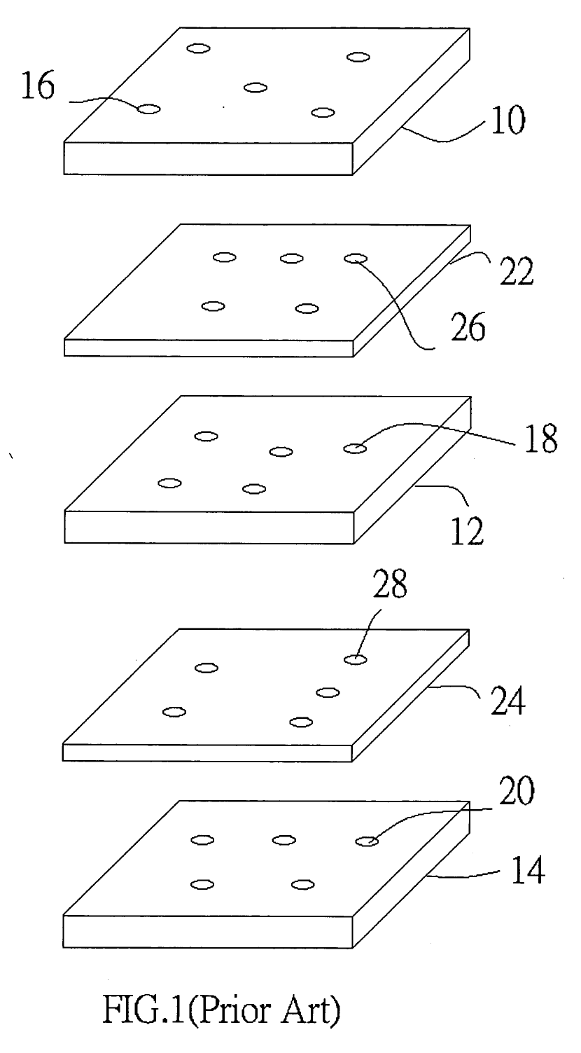

FIG. 2 is an explosion view showing a printed circuit board structure of the present invention.

FIG. 3 is a cross-sectional view showing a printed circuit board structure of the present invention.

### DETAILED DESCRIPTION OF THE INVENTION

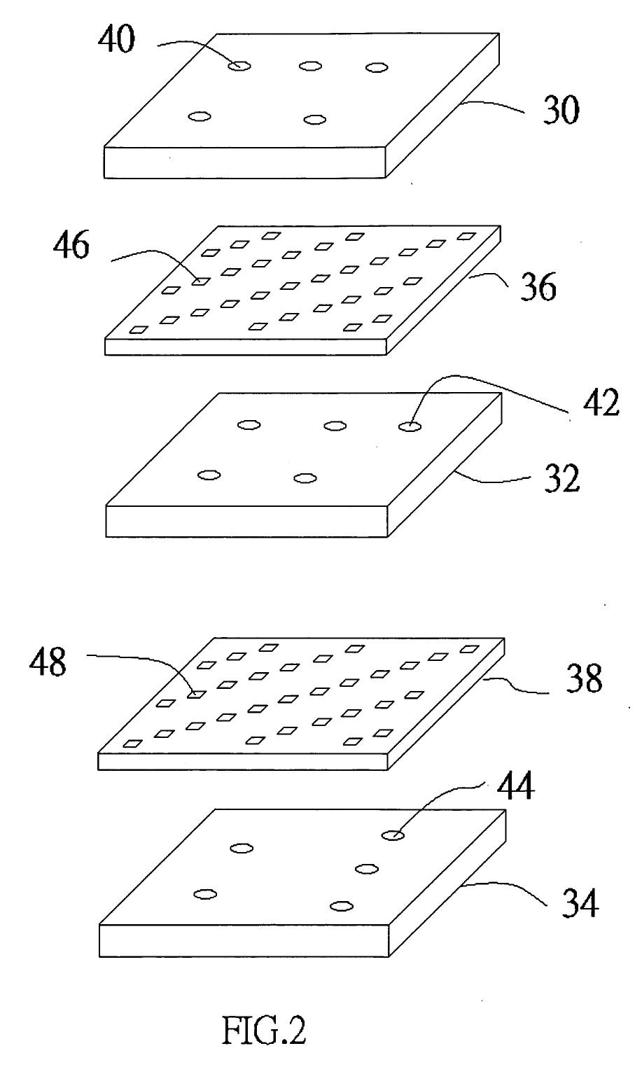

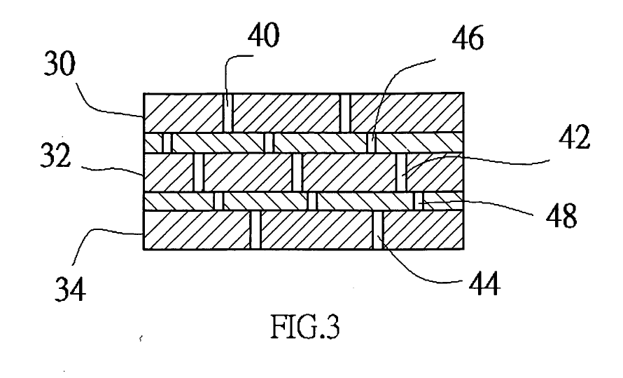

Please refer to FIG. 2 and FIG. 3. A printed circuit board of the present invention includes three layer substrates 30, 32, 34 and two layer metal sheets 36, 38.

The each substrate 30, 32, 34 are formed with a plurality of hole 40, 42, 44 for conducting the each substrate 30, 32, 34 one another.

The two layer metal sheets 36, 38 are copper, which are arranged between the two adjacent substrate 30, 32 and 32, 34. The each metal sheet is formed with grid array penetrated holes 46, 48.

Therefore, the grid array penetrated holes 46, 48 of the metal sheet 36, 38 may be absorbed bent energy from the substrate 30, 32, 34, so that the printed circuit board may be decrease the damage to increase the production yield.

While the invention has been described by way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

What is claimed is:

1. A printed circuit board structure, comprising:
at least three layer substrates, the each substrate formed with a plurality of hole for conducting the each substrate one another; and
at least two layer metal sheets being arranged between the two adjacent substrate, the each metal sheet formed with grid array penetrated holes.

2. The printed circuit board structure according to claim 1, wherein the each metal layer is made of copper.
